(19) United States
(12) Patent Application Publication
(10) Pub. No.: US 2026/0096118 A1
(43) Pub. Date: Apr. 2, 2026

(54) SEMICONDUCTOR DEVICE

(71) Applicant: Mitsubishi Electric Corporation, Tokyo (JP)

(72) Inventors: Kazuya KONISHI, Tokyo (JP); Koji TANAKA, Tokyo (JP); Reona FURUKAWA, Tokyo (JP); Takashi FUJIMOTO, Tokyo (JP); Kakeru OTSUKA, Tokyo (JP); Tetsuya HIGASHI, Tokyo (JP); Kohei SAKO, Tokyo (JP)

(73) Assignee: Mitsubishi Electric Corporation, Tokyo (JP)

(21) Appl. No.: 19/290,278

(22) Filed: Aug. 4, 2025

(30) Foreign Application Priority Data
Sep. 30, 2024 (JP) 2024-169772

(51) Int. Cl. H10D 12/00; H10D 64/23

(52) U.S. Cl. CPC H10D 12/481; H10D 64/232

(57) ABSTRACT

A semiconductor device according to the present disclosure includes: a semiconductor substrate; a base layer located in the semiconductor substrate on a side of a front surface thereof; and a two-stage dummy active trench located in the semiconductor substrate on the side of the front surface thereof to extend through the base layer, the two-stage dummy active trench including therein a first upper electrode in an upper stage connected to an emitter electrode and a first lower electrode in a lower stage connected to a gate electrode, wherein the first upper electrode includes a prong protruding from at least one of left and right portions of an end surface thereof on a side of a back surface toward the back surface, and a tip of the prong is located closer to the back surface than the base layer is.

### BACKGROUND

### Technical Field

The present disclosure relates to a semiconductor device in which conduction is controlled by a gate signal.

### Description of the Background Art

In a semiconductor device including a two-stage dummy active trench including therein an upper electrode in an upper stage connected to an emitter electrode and a lower electrode in a lower stage connected to a gate electrode, a change in voltage over time (dV/dt) causing noise and dielectric breakdown of a motor can be reduced by increasing a gate-collector capacitance (see Japanese Patent Application Laid-Open No. 2023-37881, for example).

Depending on a very fast switching condition, such as fast turn-on switching, however, holes vary a potential around the trench, and a displacement current flows into the lower electrode as a gate potential. This leads to a problem of an increase in gate voltage to cause an increase in dV/dt.

### SUMMARY

It is an object of the present disclosure to provide a semiconductor device in which dV/dt can be reduced by suppressing an increase in gate voltage.

A semiconductor device according to the present disclosure includes: a semiconductor substrate; a base layer located in the semiconductor substrate on a side of a front surface thereof; and a two-stage dummy active trench located in the semiconductor substrate on the side of the front surface thereof to extend through the base layer, the two-stage dummy active trench including therein a first upper electrode in an upper stage connected to an emitter electrode and a first lower electrode in a lower stage connected to a gate electrode, wherein the first upper electrode includes a prong protruding from at least one of left and right portions of an end surface thereof on a side of a back surface toward the back surface, and a tip of the prong is located closer to the back surface than the base layer is.

According to the present disclosure, dV/dt can be reduced by suppressing an increase in gate voltage.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to Embodiment 1;

FIG. 2 is a cross-sectional view of a semiconductor device according to Modification 1 of Embodiment 1;

FIG. 3 is a cross-sectional view of a semiconductor device according to Modification 2 of Embodiment 1;

FIG. 4 is a cross-sectional view of a semiconductor device according to Modification 3 of Embodiment 1;

FIG. 5 is a cross-sectional view of a semiconductor device according to Modification 4 of Embodiment 1;

FIG. 6 is a cross-sectional view of a semiconductor device according to Modification 5 of Embodiment 1;

FIG. 7 is a cross-sectional view of a semiconductor device according to Modification 6 of Embodiment 1;

FIG. 8 is a cross-sectional view of a semiconductor device according to Modification 7 of Embodiment 1;

FIG. 9 is a cross-sectional view of a semiconductor device according to Modification 8 of Embodiment 1;

FIG. 10 is a cross-sectional view of a semiconductor device according to Modification 9 of Embodiment 1;

FIG. 11 is a cross-sectional view of a semiconductor device according to Modification 10 of Embodiment 1;

FIG. 12 is a cross-sectional view of a semiconductor device according to Modification 11 of Embodiment 1;

FIG. 13 is a cross-sectional view of a semiconductor device according to Modification 11 of Embodiment 1;

FIG. 14 is a cross-sectional view of a semiconductor device according to Modification 11 of Embodiment 1;

FIG. 15 is a cross-sectional view of a semiconductor device according to Modification 12 of Embodiment 1; and

FIG. 16 is a cross-sectional view of a semiconductor device according to Modification 14 of Embodiment 1.

### DESCRIPTION OF THE PREFERRED EMBODIMENTS

### Embodiment 1

A semiconductor device according to an embodiment will be described below with reference to the drawings. The semiconductor device is an insulated gate bipolar transistor (IGBT). The same or corresponding components bear the same reference signs, and repeated description is sometimes omitted. In description made below, N and P indicate conductivity types of a semiconductor. These conductivity types may be reversed.

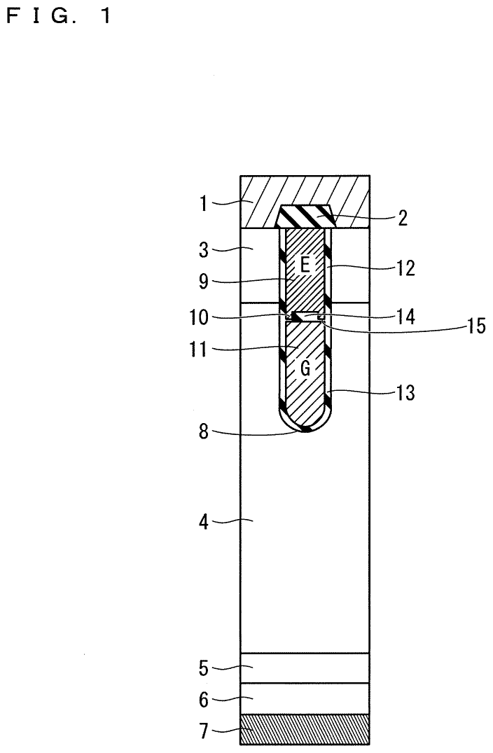

FIG. 1 is a cross-sectional view of a semiconductor device according to Embodiment 1. In FIG. 1, a semiconductor substrate is in a range from a base layer 3 to a collector layer 6. In FIG. 1, an upper end of the base layer 3 is referred to as a front surface of the semiconductor substrate, and a lower end of the collector layer 6 is referred to as a back surface of the semiconductor substrate. The front surface and the back surface face each other.

As illustrated in FIG. 1, the P-type base layer 3 is provided on a side of the front surface of an N-type drift layer 4.

The semiconductor substrate includes a two-stage dummy active trench 8 extending through the base layer 3 to the drift layer 4. The two-stage dummy active trench 8 is located in the semiconductor substrate on a side of the front surface thereof and includes therein a first upper electrode 9 in an upper stage connected to an emitter electrode 1 and a first lower electrode 11 in a lower stage connected to a gate electrode (not illustrated). The first upper electrode 9 includes, on each of left and right portions of an end surface thereof on a side of the back surface, a prong 10 protruding toward the back surface. A tip 15 of the prong 10 is located closer to the back surface than the base layer 3 is. While the prong 10 is provided on each of the left and right portions of the end surface on the side of the back surface of the first upper electrode 9 in an example of FIG. 1, the prong 10 may be provided on one of the left and right portions.

The two-stage dummy active trench 8 includes a first upper insulating film 12 provided on a side wall of the first upper electrode 9, a first lower insulating film 13 provided on a side wall of the first lower electrode 11, and a first boundary insulating film 14 provided between the first upper electrode 9 and the first lower electrode 11. The first upper electrode 9 and the first lower electrode 11 are electrically separated from each other via the first boundary insulating film 14.

An interlayer insulating film 2 is provided over the two-stage dummy active trench 8. The emitter electrode 1 is provided over the base layer 3 and the interlayer insulating film 2.

On a side of the back surface of the drift layer 4, an N-type buffer layer 5 having a higher N-type impurity concentration than the drift layer 4 is provided. The P-type collector layer 6 is provided on a side of the back surface of the buffer layer 5. A collector electrode 7 is provided on a side of the back surface of the collector layer 6.

A displacement current is generated by holes varying a potential around a trench. The displacement current is generated in a region closer to the back surface than the base layer 3, in which holes are stored, is. According to Embodiment 1, the first upper electrode 9 includes the prong 10 protruding toward the back surface, and the tip 15 of the prong 10 is located closer to the back surface than the base layer 3 is, so that the displacement current flows to the prong 10 as an emitter potential being a low potential. The number of holes flowing into the first lower electrode 11 as a gate potential decreases by the displacement current flowing to the prong 10, so that an increase in gate voltage can be reduced. That is to say, according to Embodiment 1, dV/dt can be reduced by suppressing the increase in gate voltage.

The displacement current generated by the variation in potential by the holes has a large influence especially in the IGBT, which is a bipolar device using holes as carriers. According to Embodiment 1, a synergistic effect from the IGBT and the above-mentioned configuration can be obtained to increase an effect of reducing the displacement current.

### Modification 1

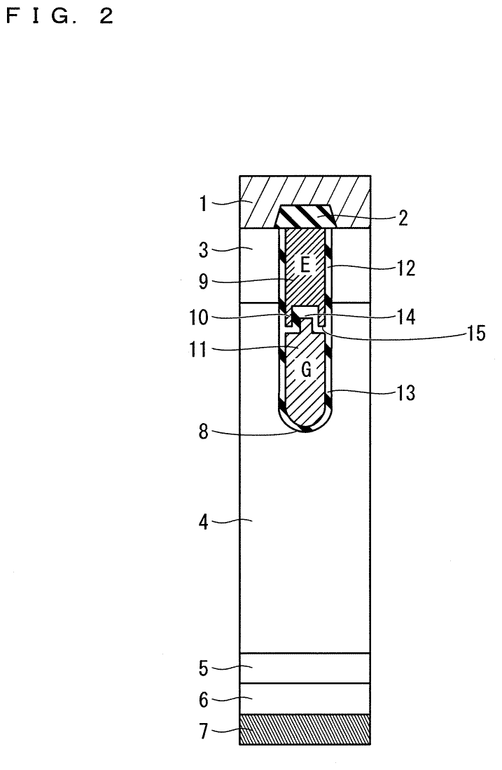

FIG. 2 is a cross-sectional view of a semiconductor device according to Modification 1 of Embodiment 1. As illustrated in FIG. 2, in the semiconductor device according to Modification 1, the prong 10 of the first upper electrode 9 and the first lower electrode 11 face each other in a width direction (transverse direction) of the two-stage dummy active trench 8.

According to Modification 1, the prong 10 of the first upper electrode 9 and the first lower electrode 11 are arranged to face each other in the width direction of the two-stage dummy active trench 8, so that the prong 10 shields the first lower electrode 11 to reduce a flow of the displacement current into the first lower electrode 11. Thus, dV/dt can be reduced by suppressing the increase in gate voltage.

### Modification 2

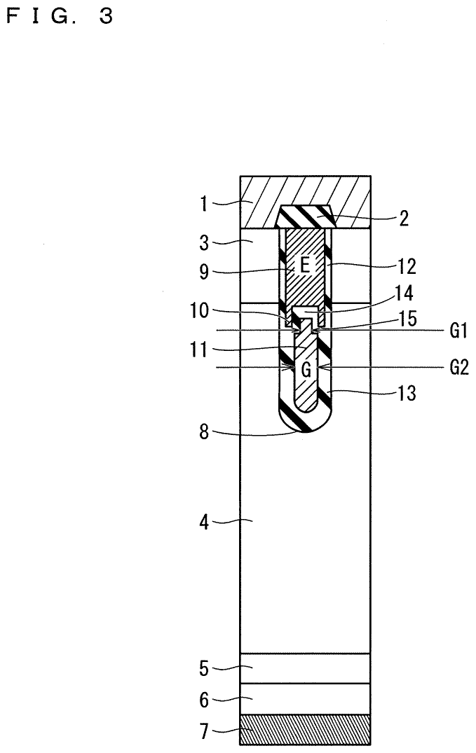

FIG. 3 is a cross-sectional view of a semiconductor device according to Modification 2 of Embodiment 1. As illustrated in FIG. 3, the first lower electrode 11 includes a portion having a first width G1 on the side of the front surface and a portion having a second width G2 greater than the first width G1 on the side of the back surface. The portion having the first width G1 faces the prong 10 in the width direction of the two-stage dummy active trench 8. The portion having the second width G2 does not face the prong 10 in the width direction of the two-stage dummy active trench 8.

According to Modification 2, the portion (portion having the first width G1) of the first lower electrode 11 facing the prong 10 of the first upper electrode 9 has a smaller width (the first width G1), so that a space into which the prong 10 can protrude toward the first lower electrode 11 is formed, and the prong 10 can be lengthened. This can increase the displacement current flowing into the prong 10 and reduce the displacement current flowing into the first lower electrode 11, so that the increase in gate voltage can be suppressed.

FIG. 3 illustrates an example in which the first lower insulating film 13 has a greater film thickness than the first upper insulating film 12. Such a configuration may be applied to Embodiment 1 and Modification 1.

### Modification 3

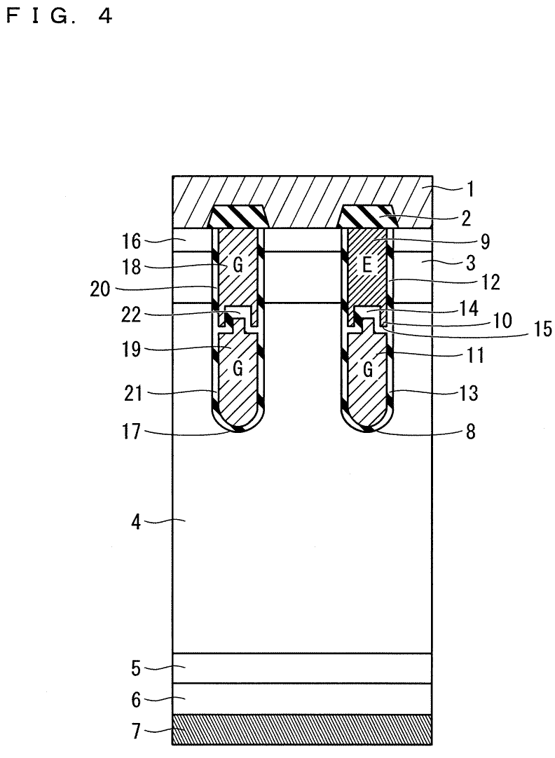

FIG. 4 is a cross-sectional view of a semiconductor device according to Modification 3 of Embodiment 1. As illustrated in FIG. 4, the semiconductor device according to Modification 3 further includes an N-type source layer 16 provided on a side of the front surface of the base layer 3 and a two-stage active trench 17 extending through the source layer 16 and the base layer 3 to the drift layer 4.

The two-stage active trench 17 is located in the semiconductor substrate on the side of the front surface and includes therein a second upper electrode 18 in an upper stage connected to the gate electrode and a second lower electrode 19 in a lower stage connected to the gate electrode.

The two-stage active trench 17 includes a second upper insulating film 20 provided on a side wall of the second upper electrode 18, a second lower insulating film 21 provided on a side wall of the second lower electrode 19, and a second boundary insulating film 22 provided between the second upper electrode 18 and the second lower electrode 19. The second upper electrode 18 and the second lower electrode 19 are electrically separated from each other via the second boundary insulating film 22.

According to Modification 3, the two-stage active trench 17 including the second upper electrode 18 as the gate potential and the source layer 16 are included, so that a channel can be formed in the base layer 3 to enable on operation of the semiconductor device.

Although the displacement current flows into the second upper electrode 18 of the two-stage active trench 17 as the second upper electrode 18 is connected to the gate electrode, the two-stage active trench 17 and the two-stage dummy active trench 8 are arranged adjacent to each other, so that a synergistic effect of enabling on operation while allowing the displacement current to flow through the first upper electrode 9 of the two-stage dummy active trench 8 can be obtained.

Shapes of the first lower electrode 11 and the second lower electrode 19 are similar to those in Modifications 1 and 2 (see FIGS. 2 and 3) in an example of FIG. 4 but are not limited to these shapes. The shapes of the first lower electrode 11 and the second lower electrode 19 may be similar to those in Embodiment 1 (see FIG. 1).

### Modification 4

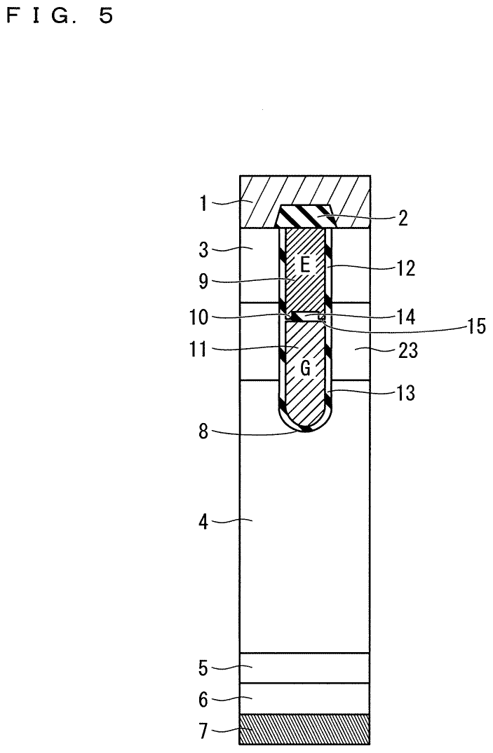

FIG. 5 is a cross-sectional view of a semiconductor device according to Modification 4 of Embodiment 1. As illustrated in FIG. 5, the semiconductor device according to Modification 4 further includes a carrier storage layer 23. The carrier storage layer 23 is provided on a side of the back surface of the base layer 3 (on a side of the front surface of the drift layer 4).

According to Modification 4, the carrier storage layer 23 is included to increase a quantity of stored holes to thereby increase the displacement current. With such a configuration, a synergistic effect from the carrier storage layer 23 and Embodiment 1 can be obtained, and, in particular, the effect of reducing the displacement current is increased.

The prong 10 of the first upper electrode 9 and the carrier storage layer 23 may be located to face each other in the width direction of the two-stage dummy active trench 8. With such a configuration, the influence of the displacement current due to densification of holes in the carrier storage layer 23 can be reduced by the prong 10.

An entire region of the prong 10 of the first upper electrode 9 and the carrier storage layer 23 may be located to face each other in the width direction of the two-stage dummy active trench 8. With such a configuration, the displacement current can further be reduced.

The prong 10 of the first upper electrode 9 and a concentration peak of the carrier storage layer 23 may be located to face each other in the width direction of the two-stage dummy active trench 8. As described above, the prong 10 is disposed at a position at which the prong 10 faces a portion of the carrier storage layer 23 subject to the influence of the displacement current due to densification of holes, so that the influence of the displacement current can be reduced.

The carrier storage layer 23 according to Modification 4 is applicable to Embodiment 1 and the other modifications.

### Modification 5

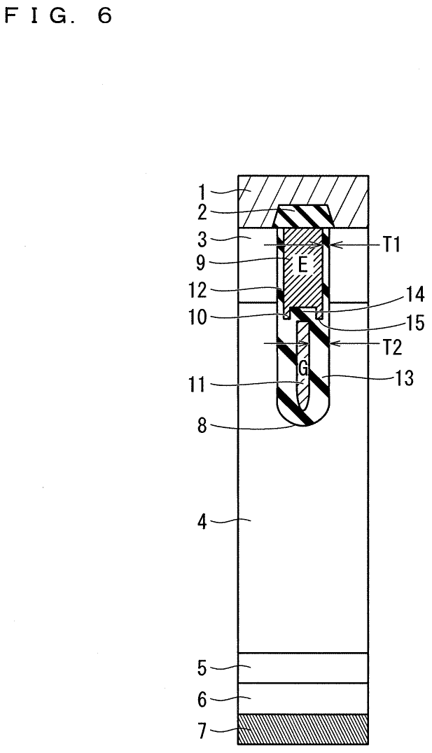

FIG. 6 is a cross-sectional view of a semiconductor device according to Modification 5 of Embodiment 1. As illustrated in FIG. 6, in the semiconductor device according to Modification 5, a film thickness T2 of the first lower insulating film 13 is greater than a film thickness T1 of the first upper insulating film 12.

According to Modification 5, the film thickness T2 of the first lower insulating film 13 is greater than the film thickness T1 of the first upper insulating film 12, so that the space into which the prong 10 of the first upper electrode 9 can protrude toward the first lower electrode 11 is formed, and the prong 10 can be lengthened. This can increase the displacement current flowing into the prong 10 and reduce the displacement current flowing into the first lower electrode 11, so that the increase in gate voltage can be suppressed.

While the prong 10 and the first lower electrode 11 face each other in the width direction of the two-stage dummy active trench 8 in an example of FIG. 6, the positional relationship between them is not limited to this positional relationship. The prong 10 and the first lower electrode 11 may not face each other in the width direction of the two-stage dummy active trench 8.

### Modification 6

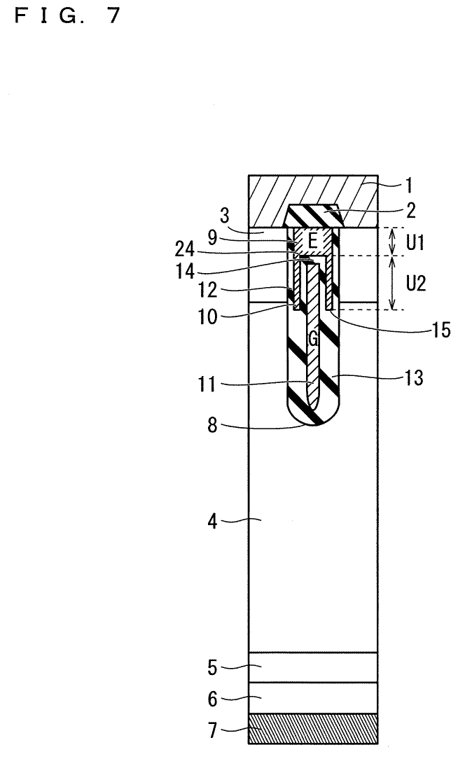

FIG. 7 is a cross-sectional view of a semiconductor device according to Modification 6 of Embodiment 1. As illustrated in FIG. 7, in the semiconductor device according to Modification 6, a length U2 of the prong 10 is greater than a length U1 from an end surface of the first upper electrode 9 on a side of the front surface to a root 24 of the prong 10.

According to Modification 6, the length U2 of the prong 10 is greater than the length U1 from the end surface of the first upper electrode 9 on the side of the front surface to the root 24 of the prong 10, so that the prong 10 can be lengthened. This can increase the displacement current flowing into the prong 10 and reduce the displacement current flowing into the first lower electrode 11, so that the increase in gate voltage can be suppressed.

The first lower electrode 11 can be lengthened toward the front surface, so that wiring resistance of the first lower electrode 11 can be reduced, and an increase in gate potential determined by the product of the wiring resistance and the displacement current can be suppressed.

While the prong 10 and the first lower electrode 11 face each other in the width direction of the two-stage dummy active trench 8 in an example of FIG. 7, the positional relationship between them is not limited to this positional relationship. The prong 10 and the first lower electrode 11 may not face each other in the width direction of the two-stage dummy active trench 8.

### Modification 7

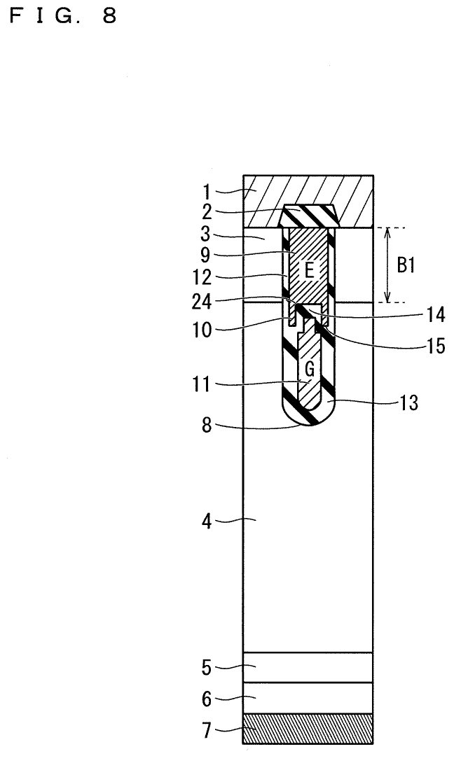

FIG. 8 is a cross-sectional view of a semiconductor device according to Modification 7 of Embodiment 1. As illustrated in FIG. 8, in the semiconductor device according to Modification 7, the root 24 of the prong 10 of the first upper electrode 9 is located closer to the back surface than the base layer 3 (a position away from the front surface of the semiconductor substrate by B1) is.

In a layer closer to the back surface than the base layer 3 is, holes are stored, and the displacement current is likely to be generated. According to Modification 7, the root 24 of the prong 10 as a whole is disposed closer to the back surface than the base layer 3 is, so that the displacement current flowing into the prong 10 can be increased and the displacement current flowing into the first lower electrode 11 can be reduced, and thus the increase in gate voltage can be suppressed.

While the prong 10 and the first lower electrode 11 face each other in the width direction of the two-stage dummy active trench 8 in an example of FIG. 8, the positional relationship between them is not limited to this positional relationship. The prong 10 and the first lower electrode 11 may not face each other in the width direction of the two-stage dummy active trench 8.

The shape of the first lower electrode 11 is similar to that in Modifications 1 and 2 (see FIGS. 2 and 3) in the example of FIG. 8 but is not limited to this shape. The shape of the first lower electrode 11 may be similar to that in Embodiment 1 (see FIG. 1).

### Modification 8

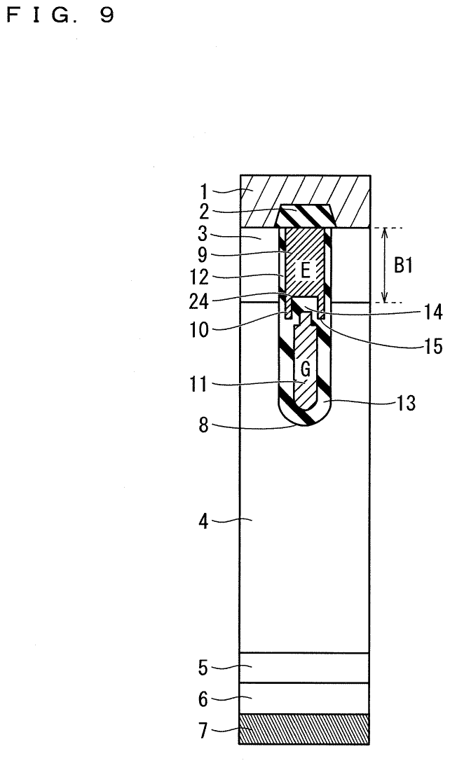

FIG. 9 is a cross-sectional view of a semiconductor device according to Modification 8 of Embodiment 1. As illustrated in FIG. 9, in the semiconductor device according to Modification 8, the root 24 of the prong 10 of the first upper electrode 9 is located closer to the front surface than an end surface of the base layer 3 on a side of the back surface (the position away from the front surface of the semiconductor substrate by B1) is. The tip 15 of the prong 10 is located closer to the back surface than the base layer 3 is as in Embodiment 1.

According to Modification 8, the root 24 of the prong 10 is disposed closer to the front surface than the end surface of the base layer 3 on the side of the back surface is, so that the displacement current flowing into the prong 10 can be increased and the displacement current flowing into the first lower electrode 11 can be reduced while a region of the first lower electrode 11 can be extended toward the front surface to reduce wiring resistance of the first lower electrode 11, and thus the increase in gate voltage can be suppressed.

While the prong 10 and the first lower electrode 11 face each other in the width direction of the two-stage dummy active trench 8 in an example of FIG. 9, the positional relationship between them is not limited to this positional relationship. The prong 10 and the first lower electrode 11 may not face each other in the width direction of the two-stage dummy active trench 8.

The shape of the first lower electrode 11 is similar to that in Modifications 1 and 2 (see FIGS. 2 and 3) in the example of FIG. 9 but is not limited to this shape. The shape of the first lower electrode 11 may be similar to that in Embodiment 1 (see FIG. 1).

### Modification 9

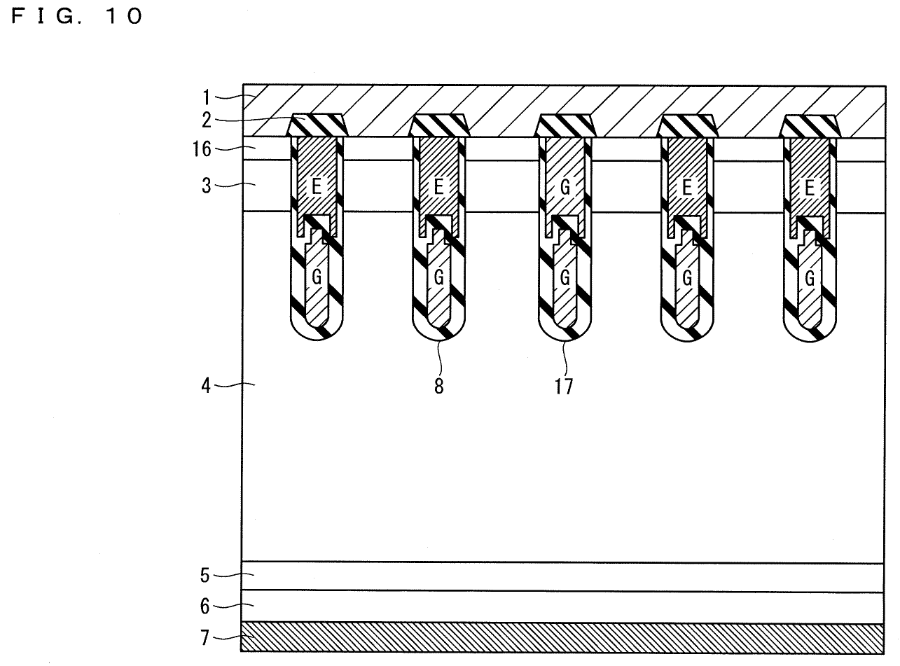

FIG. 10 is a cross-sectional view of a semiconductor device according to Modification 9 of Embodiment 1. As illustrated in FIG. 10, in the semiconductor device according to Modification 9, the two-stage dummy active trench 8 is disposed adjacent to the two-stage active trench 17 on each of opposite sides of the two-stage active trench 17. While two two-stage dummy active trenches 8 are arranged on each of the opposite sides of the two-stage active trench 17 in an example of FIG. 10, the number of two-stage dummy active trenches 8 is not limited to two.

According to Modification 9, the two-stage dummy active trench 8 is disposed adjacent to the two-stage active trench 17 on each of the opposite sides of the two-stage active trench 17, so that the displacement current flowing into the second upper electrode 18 of the two-stage active trench 17 is allowed to flow to the first upper electrode 9 of the two-stage dummy active trench 8, and thus the increase in gate voltage due to the displacement current can be suppressed.

The number of two-stage dummy active trenches 8 may be greater than the number of two-stage active trenches 17. With such a configuration, the effect of reducing the displacement current can further be increased.

While the prong 10 and the first lower electrode 11 in the two-stage dummy active trench 8 face each other in the width direction of the two-stage dummy active trench 8 in the example of FIG. 10, the positional relationship between them is not limited to this positional relationship. The prong 10 and the first lower electrode 11 may not face each other in the width direction of the two-stage dummy active trench 8. The same applies to the two-stage active trench 17.

The shape of the first lower electrode 11 is similar to that in Modifications 1 and 2 (see FIGS. 2 and 3) in the example of FIG. 10 but is not limited to this shape. The shape of the first lower electrode 11 may be similar to that in Embodiment 1 (see FIG. 1). The same applies to the two-stage active trench 17.

### Modification 10

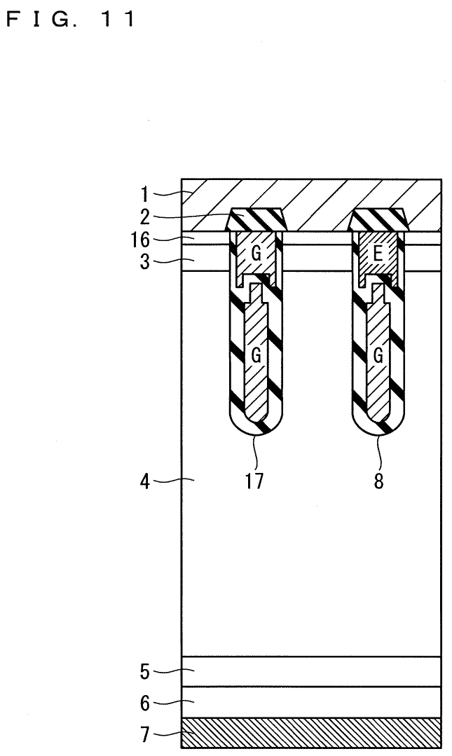

FIG. 11 is a cross-sectional view of a semiconductor device according to Modification 10 of Embodiment 1. As illustrated in FIG. 11, in the semiconductor device according to Modification 10, the first upper electrode 9 has a smaller cross-sectional area than the first lower electrode 11 in the two-stage dummy active trench 8. Furthermore, the second upper electrode 18 has a smaller cross-sectional area than the second lower electrode 19 in the two-stage active trench 17.

The cross-sectional area of each of the first lower electrode 11 and the second lower electrode 19 is increased, so that wiring resistance of each of the first lower electrode 11 and the second lower electrode 19 can be reduced, and thus the increase in gate voltage can be suppressed.

While the prong 10 and the first lower electrode 11 in the two-stage dummy active trench 8 face each other in the width direction of the two-stage dummy active trench 8 in an example of FIG. 11, the positional relationship between them is not limited to this positional relationship. The prong 10 and the first lower electrode 11 may not face each other in the width direction of the two-stage dummy active trench 8. The same applies to the two-stage active trench 17.

The shape of the first lower electrode 11 is similar to that in Modifications 1 and 2 (see FIGS. 2 and 3) in the example of FIG. 11 but is not limited to this shape. The shape of the first lower electrode 11 may be similar to that in Embodiment 1 (see FIG. 1). The same applies to the two-stage active trench 17.

### Modification 11

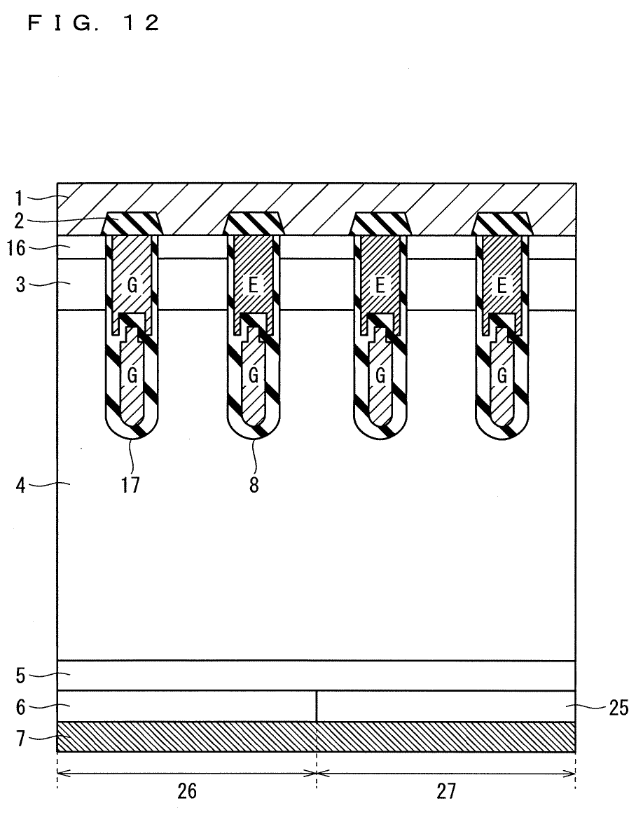

FIG. 12 is a cross-sectional view of a semiconductor device according to Modification 11 of Embodiment 1. As illustrated in FIG. 12, the semiconductor device according to Modification 11 is a reverse conducting IGBT (RC-IGBT) including an IGBT region 26 including the collector layer 6 and a diode region 27 including a cathode layer 25 provided in the semiconductor substrate on a side of the back surface thereof. The two-stage active trench 17 and the two-stage dummy active trench 8 are arranged in the IGBT region 26, and two-stage dummy active trenches 8 are arranged in the diode region 27.

A similar effect to that obtained in Embodiment 1 can be obtained in an RC-IGBT as in Modification 11. In particular, the two-stage dummy active trenches 8 are arranged in the diode region 27 in which no gate is necessary, so that the displacement current generated in the IGBT region 26 can be drawn to the two-stage dummy active trenches 8, and thus the increase in gate voltage can be suppressed.

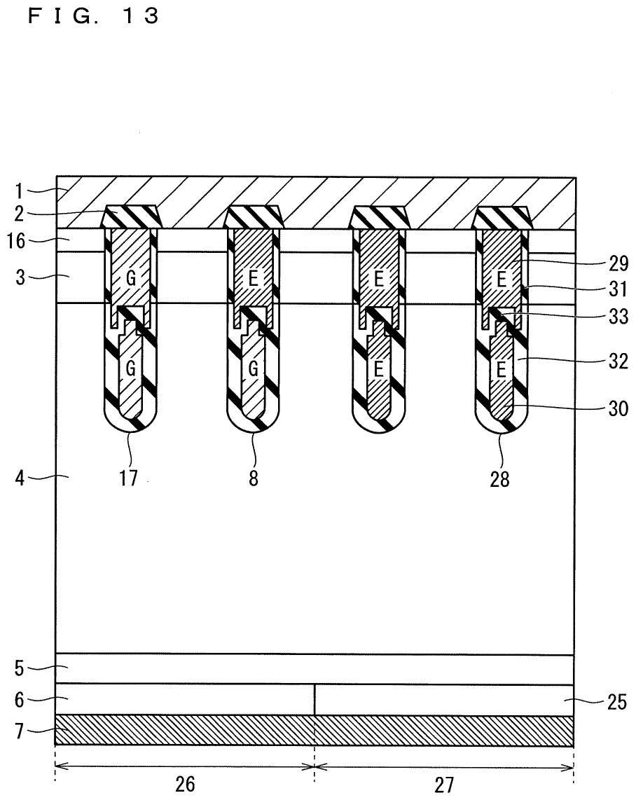

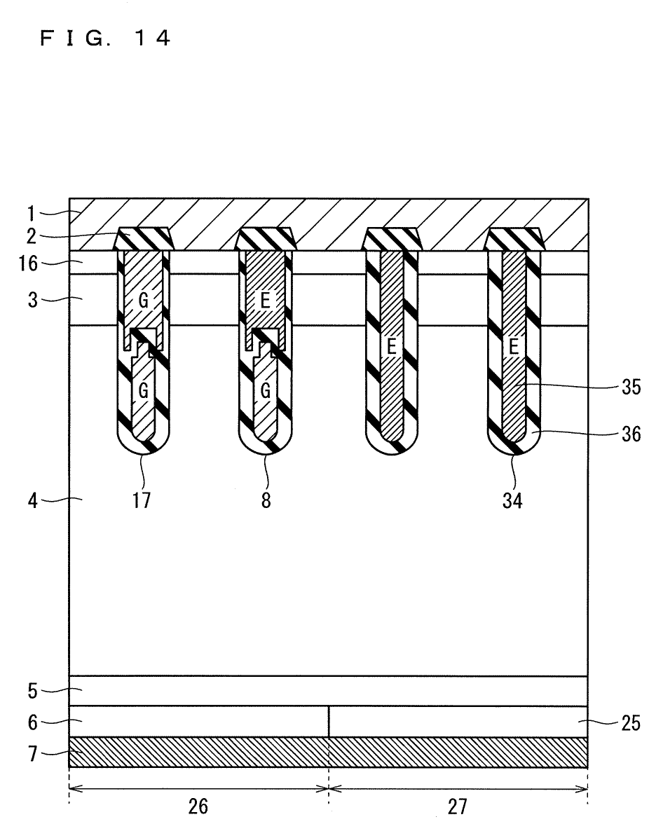

A configuration of the semiconductor device according to Modification 11 is not limited to the configuration illustrated in FIG. 12 and may be a configuration illustrated in FIG. 13 or FIG. 14.

In the semiconductor device illustrated in FIG. 13, two-stage dummy trenches 28 are arranged in the diode region 27. The two-stage dummy trenches 28 are each located in the semiconductor substrate on the side of the front surface and each include therein a third upper electrode 29 in an upper stage connected to the emitter electrode 1 and a third lower electrode 30 in a lower stage connected to the emitter electrode 1. The two-stage dummy trench 28 also includes a third upper insulating film 31 provided on a side wall of the third upper electrode 29, a third lower insulating film 32 provided on a side wall of the third lower electrode 30, and a third boundary insulating film 33 provided between the third upper electrode 29 and the third lower electrode 30. The third upper electrode 29 and the third lower electrode 30 are electrically separated from each other via the third boundary insulating film 33.

In a semiconductor device illustrated in FIG. 14, one-stage dummy trenches 34 are arranged in the diode region 27. The one-stage dummy trenches 34 are each located in the semiconductor substrate on the side of the front surface and each include therein a dummy electrode 35 and a dummy insulating film 36 provided on a side wall of the dummy electrode 35.

The semiconductor device has the configuration illustrated in FIG. 13 or FIG. 14, so that the displacement current flowing into the first lower electrode 11 in the two-stage dummy active trench 8 and the second lower electrode 19 in the two-stage active trench 17 arranged in the IGBT region 26 can be reduced.

In the diode region 27, the two-stage dummy active trench 8 illustrated in FIG. 12, the two-stage dummy trench 28 illustrated in FIG. 13, and the one-stage dummy trench 34 illustrated in FIG. 14 may be combined as appropriate to be arranged.

While the prong 10 and the first lower electrode 11 in the two-stage dummy active trench 8 face each other in the width direction of the two-stage dummy active trench 8 in each of examples of FIGS. 12 to 14, the positional relationship between them is not limited to this positional relationship. The prong 10 and the first lower electrode 11 may not face each other in the width direction of the two-stage dummy active trench 8. The same applies to the two-stage active trench 17 and the two-stage dummy trench 28.

The shape of the first lower electrode 11 is similar to that in Modifications 1 and 2 (see FIGS. 2 and 3) in each of the examples of FIGS. 12 to 14 but is not limited to this shape. The shape of the first lower electrode 11 may be similar to that in Embodiment 1 (see FIG. 1). The same applies to the two-stage active trench 17 and the two-stage dummy trench 28.

### Modification 12

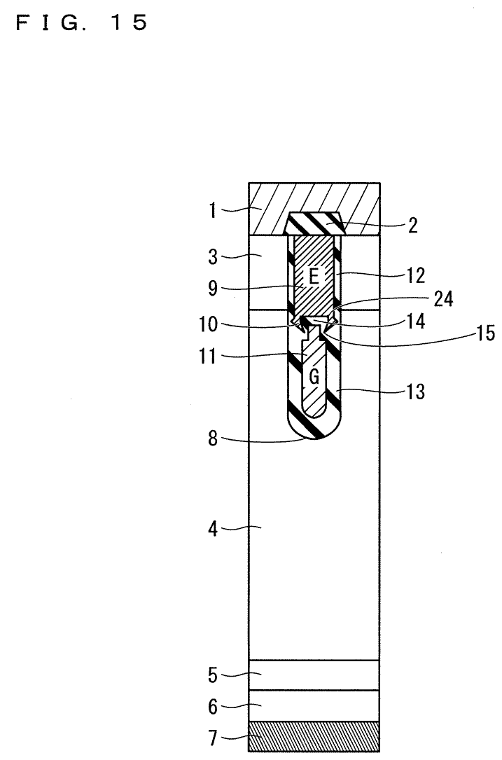

FIG. 15 is a cross-sectional view of a semiconductor device according to Modification 12 of Embodiment 1. As illustrated in FIG. 15, in the semiconductor device according to Modification 12, a portion of the first upper insulating film 12 facing the prong 10 has a smaller film thickness than the other portion of the first upper insulating film 12 and the first lower insulating film 13.

According to Modification 12, the portion of the first upper insulating film 12 facing the prong 10 has a smaller film thickness than the other portion of the first upper insulating film 12 and the first lower insulating film 13, so that the displacement current can preferentially flow into the prong 10, and thus the influence of the displacement current on the gate voltage can be reduced.

The portion of the first upper insulating film 12 facing the prong 10 may have a greater film thickness than the other portion of the first upper insulating film 12. With such a configuration, the total amount of the displacement current can be reduced while ease of the flow of the displacement current into the prong 10 is maintained. A flow of a large amount of the displacement current into the first upper electrode 9 causes a voltage drop and might affect the gate potential of the first lower electrode 11. According to Modification 12, the total amount of the displacement current is reduced, so that the variation in gate potential can be reduced.

The shape of the first lower electrode 11 is similar to that in Modifications 1 and 2 (see FIGS. 2 and 3) in an example of FIG. 15 but is not limited to this shape. The shape of the first lower electrode 11 may be similar to that in Embodiment 1 (see FIG. 1).

### Modification 13

In a semiconductor device according to Modification 13, the semiconductor substrate includes a wide bandgap semiconductor. Examples of the wide bandgap semiconductor include SiC (silicon carbide), GaN (gallium nitride), and Ga₂O₃ (gallium oxide).

A similar effect to that obtained in Embodiment 1 can be obtained even in a configuration in which the semiconductor substrate includes the wide bandgap semiconductor as in Modification 13. In particular, the wide bandgap semiconductor enables fast switching compared with Si, so that the displacement current increases due to an increase in dV/dt. The semiconductor device according to the present disclosure includes the two-stage dummy active trench 8 including the first upper electrode 9 including the prong 10, so that the displacement current can flow to the first upper electrode 9. Thus, especially in the wide bandgap semiconductor in which the displacement current increases, the increase in gate voltage can be suppressed.

### Modification 14

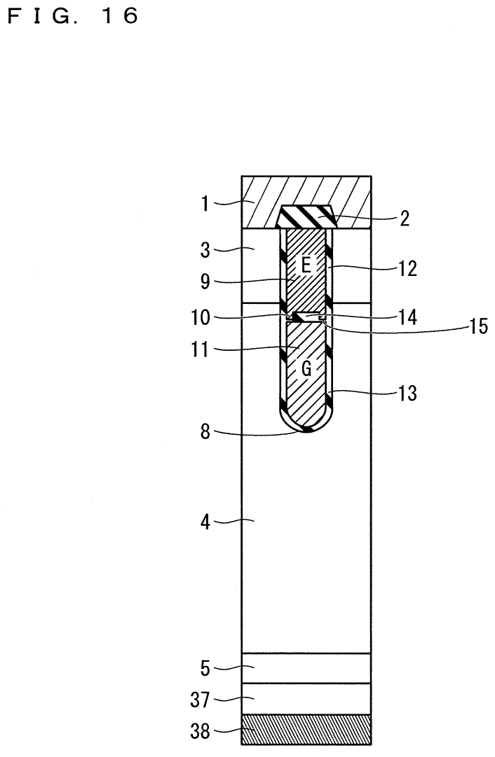

FIG. 16 is a cross-sectional view of a semiconductor device according to Modification 14 of Embodiment 1. As illustrated in FIG. 16, the semiconductor device according to Modification 14 is a metal oxide semiconductor field effect transistor (MOSFET) including a drain layer 37 provided in the semiconductor substrate on a side of the back surface and a drain electrode 38 provided on a side of the back surface of the drain layer 37. The other configuration is similar to that in Embodiment 1 (see FIG. 1).

The MOSFET is a unipolar device in which holes do not contribute to on operation, so that the influence of the displacement current due to the holes is small. On the other hand, the MOSFET can make switching faster due to the absence of the holes to increase dV/dt. The displacement current is determined by the product of dV/dt and Cgd (a gate-drain capacitance) and thus increases in the MOSFET during high-frequency operation. According to Modification 14, the two-stage dummy active trench 8 including the first upper electrode 9 including the prong 10 is included, so that the displacement current can flow to the first upper electrode 9, and the increase in gate voltage can be suppressed.

The shape of the first lower electrode 11 is similar to that in Embodiment 1 (see FIG. 1) in an example of FIG. 16 but is not limited to this shape. The shape of the first lower electrode 11 may be similar to that in Modifications 1 and 2 (see FIGS. 2 and 3).

The embodiment can be modified or omitted as appropriate within the scope of the present disclosure.

### Appendices

Various aspects of the present disclosure will collectively be described below as appendices.

### Appendix 1

A semiconductor device comprising:
a semiconductor substrate;
a base layer located in the semiconductor substrate on a side of a front surface thereof; and
a two-stage dummy active trench located in the semiconductor substrate on the side of the front surface thereof to extend through the base layer, the two-stage dummy active trench including therein a first upper electrode in an upper stage connected to an emitter electrode and a first lower electrode in a lower stage connected to a gate electrode, wherein
the first upper electrode includes a prong protruding from at least one of left and right portions of an end surface thereof on a side of a back surface toward the back surface, and
a tip of the prong is located closer to the back surface than the base layer is.

### Appendix 2

The semiconductor device according to Appendix 1, wherein
the prong and the first lower electrode face each other in a width direction of the trench.

### Appendix 3

The semiconductor device according to Appendix 1 or 2, wherein
the first lower electrode includes a portion having a first width on the side of the front surface and a portion having a second width greater than the first width on the side of the back surface,
the portion having the first width faces the prong in the width direction of the trench, and
the portion having the second width does not face the prong in the width direction of the trench.

### Appendix 4

The semiconductor device according to any one of Appendices 1 to 3, further comprising
a two-stage active trench located in the semiconductor substrate on the side of the front surface thereof to extend through the base layer, the two-stage active trench including a second upper electrode in an upper stage connected to the gate electrode and a second lower electrode in a lower stage connected to the gate electrode.

### Appendix 5

The semiconductor device according to any one of Appendices 1 to 4, wherein
the semiconductor device is an insulated gate bipolar transistor (IGBT) including a collector layer located in the semiconductor substrate on the side of the back surface thereof.

### Appendix 6

The semiconductor device according to any one of Appendices 1 to 5, further comprising
a carrier storage layer located on a side of the back surface of the base layer.

### Appendix 7

The semiconductor device according to any one of Appendices 1 to 6, wherein
the two-stage dummy active trench includes a first upper insulating film located on a side wall of the first upper electrode and a first lower insulating film located on a side wall of the first lower electrode, and
the first lower insulating film has a greater film thickness than the first upper insulating film.

### Appendix 8

The semiconductor device according to any one of Appendices 1 to 7, wherein
the prong has a greater length than a portion of the first upper electrode from an end surface thereof on the side of the front surface to a root of the prong.

### Appendix 9

The semiconductor device according to any one of Appendices 1 to 8, wherein
a root of the prong is located closer to the back surface than the base layer is.

### Appendix 10

The semiconductor device according to any one of Appendices 1 to 8, wherein
a root of the prong is located closer to the front surface than an end surface on the side of the back surface of the base layer is.

### Appendix 11

The semiconductor device according to Appendix 4, wherein
the two-stage dummy active trench is disposed adjacent to the two-stage active trench on each of opposite sides of the two-stage active trench.

### Appendix 12

The semiconductor device according to any one of Appendices 1 to 11, wherein
the first upper electrode has a smaller cross-sectional area than the first lower electrode.

### Appendix 13

The semiconductor device according to any one of Appendices 1 to 12, wherein
the semiconductor device is a reverse conducting IGBT (an RC-IGBT) including an IGBT region including a collector layer located in the semiconductor substrate on the side of the back surface and a diode region including a cathode layer located in the semiconductor substrate on the side of the back surface.

### Appendix 14

The semiconductor device according to any one of Appendices 1 to 13, wherein
the two-stage dummy active trench includes a first upper insulating film located on a side wall of the first upper electrode and a first lower insulating film located on a side wall of the first lower electrode, and
a portion of the first upper insulating film facing the prong has a smaller film thickness than the other portion of the first upper insulating film and the first lower insulating film.

### Appendix 15

The semiconductor device according to any one of Appendices 1 to 14, wherein
the semiconductor substrate includes a wide bandgap semiconductor.

### Appendix 16

The semiconductor device according to any one of Appendices 1 to 3, wherein
the semiconductor device is a metal oxide semiconductor field effect transistor (MOSFET) including a drain layer located in the semiconductor substrate on the side of the back surface.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a base layer located in the semiconductor substrate on a side of a front surface thereof; and
a two-stage dummy active trench located in the semiconductor substrate on the side of the front surface thereof to extend through the base layer, the two-stage dummy active trench including therein a first upper electrode in an upper stage connected to an emitter electrode and a first lower electrode in a lower stage connected to a gate electrode, wherein
the first upper electrode includes a prong protruding from at least one of left and right portions of an end surface thereof on a side of a back surface toward the back surface, and
a tip of the prong is located closer to the back surface than the base layer is.

2. The semiconductor device according to claim 1, wherein
the prong and the first lower electrode face each other in a width direction of the trench.

3. The semiconductor device according to claim 2, wherein
the first lower electrode includes a portion having a first width on the side of the front surface and a portion having a second width greater than the first width on the side of the back surface,
the portion having the first width faces the prong in the width direction of the trench, and
the portion having the second width does not face the prong in the width direction of the trench.

4. The semiconductor device according to claim 1, further comprising
a two-stage active trench located in the semiconductor substrate on the side of the front surface thereof to extend through the base layer, the two-stage active trench including a second upper electrode in an upper stage connected to the gate electrode and a second lower electrode in a lower stage connected to the gate electrode.

5. The semiconductor device according to claim 1, wherein
the semiconductor device is an insulated gate bipolar transistor (IGBT) including a collector layer located in the semiconductor substrate on the side of the back surface thereof.

6. The semiconductor device according to claim 1, further comprising
a carrier storage layer located on a side of the back surface of the base layer.

7. The semiconductor device according to claim 1, wherein
the two-stage dummy active trench includes a first upper insulating film located on a side wall of the first upper electrode and a first lower insulating film located on a side wall of the first lower electrode, and
the first lower insulating film has a greater film thickness than the first upper insulating film.

8. The semiconductor device according to claim 1, wherein
the prong has a greater length than a portion of the first upper electrode from an end surface thereof on the side of the front surface to a root of the prong.

9. The semiconductor device according to claim 1, wherein
a root of the prong is located closer to the back surface than the base layer is.

10. The semiconductor device according to claim 1, wherein
a root of the prong is located closer to the front surface than an end surface on the side of the back surface of the base layer is.

11. The semiconductor device according to claim 4, wherein
the two-stage dummy active trench is disposed adjacent to the two-stage active trench on each of opposite sides of the two-stage active trench.

12. The semiconductor device according to claim 1, wherein
the first upper electrode has a smaller cross-sectional area than the first lower electrode.

13. The semiconductor device according to claim 1, wherein
the semiconductor device is a reverse conducting IGBT (an RC-IGBT) including an IGBT region including a collector layer located in the semiconductor substrate on the side of the back surface and a diode region including a cathode layer located in the semiconductor substrate on the side of the back surface.

14. The semiconductor device according to claim 1, wherein
the two-stage dummy active trench includes a first upper insulating film located on a side wall of the first upper electrode and a first lower insulating film located on a side wall of the first lower electrode, and
a portion of the first upper insulating film facing the prong has a smaller film thickness than the other portion of the first upper insulating film and the first lower insulating film.

15. The semiconductor device according to claim 1, wherein
the semiconductor substrate includes a wide bandgap semiconductor.

16. The semiconductor device according to claim 1, wherein
the semiconductor device is a metal oxide semiconductor field effect transistor (MOSFET) including a drain layer located in the semiconductor substrate on the side of the back surface.
